(19) United States
(12) Patent Application Publication
(10) Pub. No.: US 2014/0313649 A1
(43) Pub. Date: Oct. 23, 2014

(54) PORTABLE DISPLAY DEVICE

(71) Applicant: HON HAI PRECISION INDUSTRY CO., LTD., New Taipei (TW)

(72) Inventor: FU-KUO HUANG, New Taipei (TW)

(73) Assignee: HON HAI PRECISION INDUSTRY CO., LTD., New Taipei (TW)

(21) Appl. No.: 14/141,758

(22) Filed: Dec. 27, 2013

(30) Foreign Application Priority Data
Apr. 19, 2013 (TW) 102113927

(51) Int. Cl. H05K 5/02

(52) U.S. Cl. CPC H05K 5/0247
USPC 361/679.01

(57) ABSTRACT

A display includes an enclosure, a display body, a cable, and a support base. The enclosure includes a recess portion and at least one first post located in the recess portion. The display body is mounted in the enclosure. The cable is connected to the display body and received in the recess portion. The cable weaves around the first post. The support base is pivotably mounted to the enclosure and received in the recess portion.

### BACKGROUND

1. Technical Field

The present disclosure generally relates to a display capable of receiving a cable.

2. Description of Related Art

Portable display devices include cables to connect to other electronic devices. However, the cables of the portable display devices are disorderly when the portable display devices are transported or not currently connected to other electronic devices.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a portable display device.

FIG. 2 is an assembled view of FIG. 1, the portable display device being in a first open position.

FIG. 3 is an assembled view of FIG. 1, the portable display device being in a second open position.

FIG. 4 is an assembled view of FIG. 1, the portable display device being in a closed position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

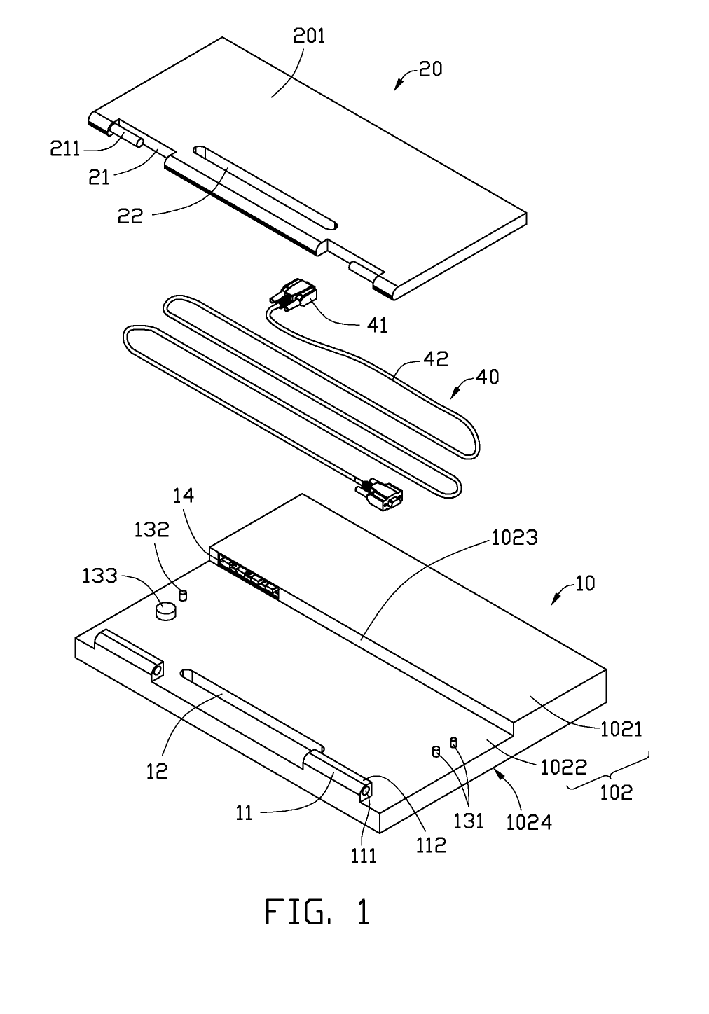

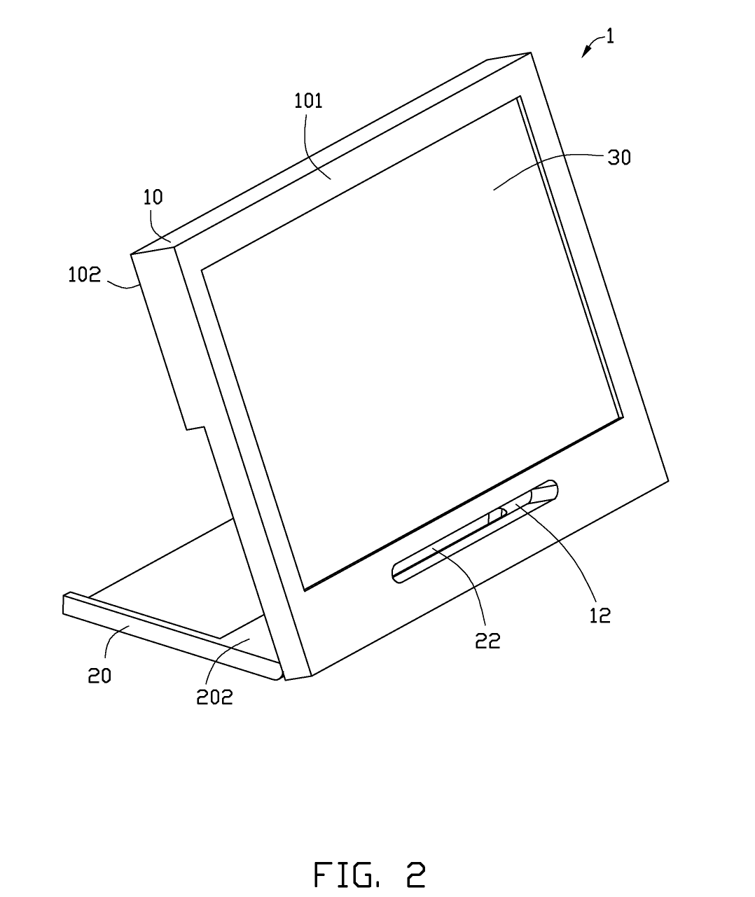

FIGS. 1 and 2 show one embodiment of a display 1. The display 1 includes an enclosure 10, a display body 30 mounted in the enclosure 10, a support base 20 mounted to a bottom portion of the enclosure 10, and a cable 40.

The enclosure 10 includes a front portion 101 and a back portion 102. The display body 30 is mounted to the front portion 101. The back portion 102 includes a raised portion 1021 and a recessed portion 1022. A side surface 1023 is formed substantially perpendicularly between the raised portion 1021 and the recessed portion 1022. The recessed portion 1022 includes a bottom surface 1024. The display body 30 includes a plurality of connectors 14 received in the side surface 1023. The cable 40 includes a cable body 42 and two connecting heads 41 connected to two ends of the cable body 42, respectively. A first connecting head 41 connects to one of the connectors 14. A second connecting head 41 connects to another electronic device (not shown).

The display 1 further includes two first positioning posts 131, a second positioning post 132, and a third positioning post 133. The two first positioning posts 131, the second positioning post 132, and the third positioning post 133 extend from the bottom surface 1024. The cable body 42 weaves around the first positioning post 131, the second positioning post 132, and the third positioning post 133. In one embodiment, a distance between the two first positioning posts 131 is more than two times a width of the cable body 42.

The display 1 further includes two pivot portions 11 located on the bottom surface 1024. Each pivot portion 11 defines a pivot hole 111. The enclosure 10 further defines a first elongated through hole 12 in the recessed portion 1022 and the front portion 101.

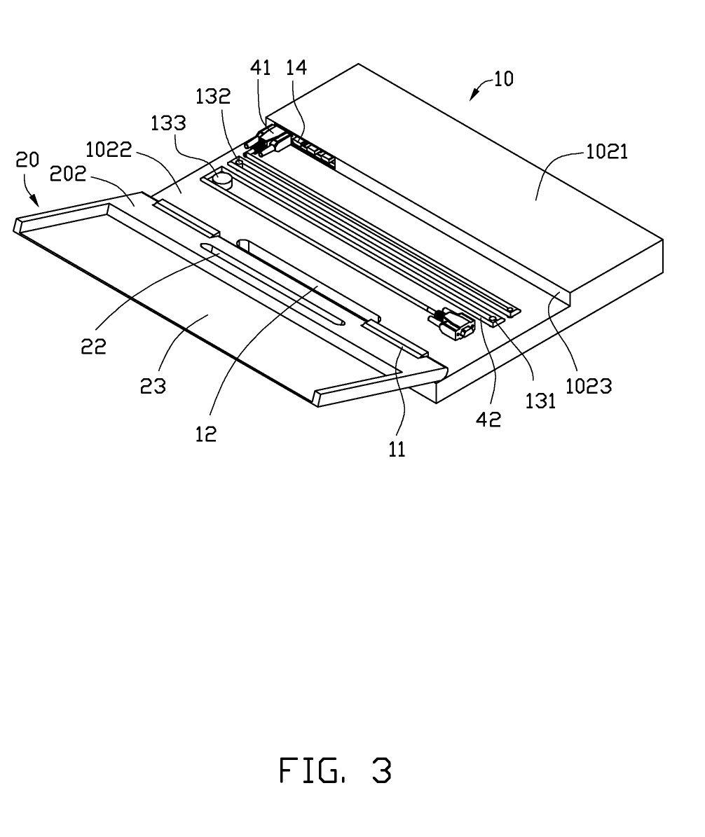

FIGS. 1 and 3 show that in one embodiment, the support base 20 is substantially rectangular. The support base 20 defines two cutouts 21. The support base 20 includes a pivot post 211 extending into each cutout 21. The pivot posts 211 correspond to the pivot holes 111. The support base 20 defines a second elongated through hole 22 corresponding to the first elongated through hole 12. The first elongated through hole 12 and the second elongated through hole 22 allow a user to easily carry the display 1. The support base 20 includes an outer surface 201 and an inner surface 202. A recess space 23 is defined in the inner surface 202 for receiving the cable 40.

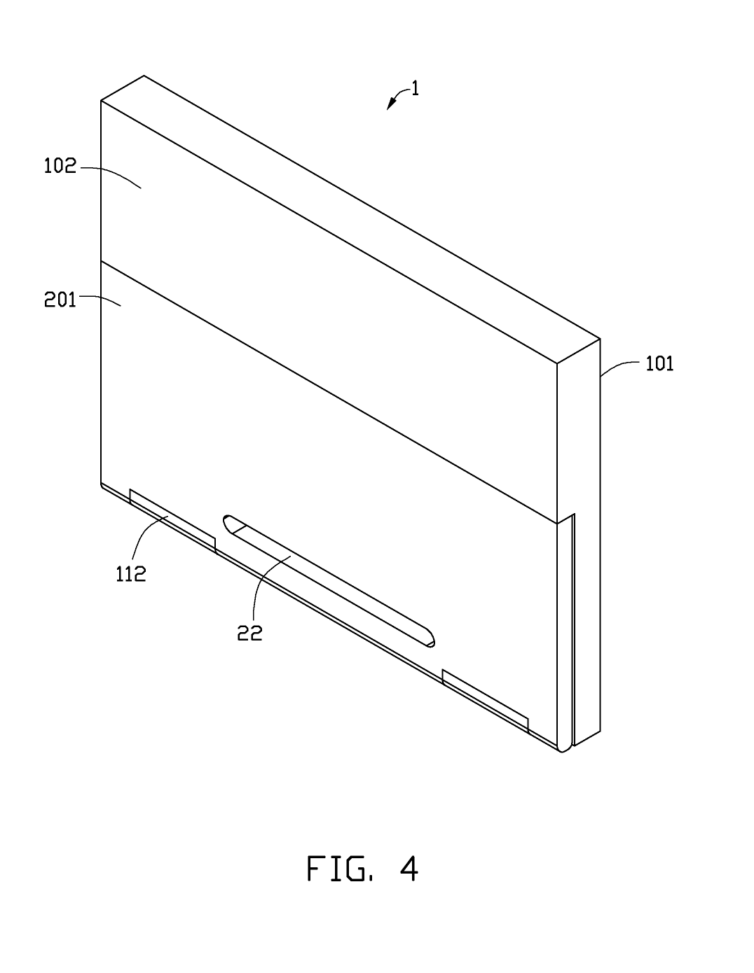

FIGS. 2 to 4 show that in assembly, each pivot post 211 is received in the corresponding pivot hole 111 of the pivot portion 11 to pivotably mount the support base 20 to the enclosure 10.

In use, the support base 20 is rotated to an open position. In one embodiment, an acute angle is defined between the support base 20 and the enclosure 10. A frictional force between the pivot posts 211 and corresponding sidewalls bounding the pivot holes 111 hold the support base 20 in the open position. The support base 20 supports the enclosure 10 in the open position. The first connecting head 41 of the cable 40 is connected to one connector 14. The second connecting head 41 is connected to another electronic device.

When the display 1 is not in use, the second connecting head 41 is disconnected from the electronic device. The cable body 42 of the cable 40 is wound around one of the first positioning posts 131 adjacent to the side surface 1023, the second positioning post 132, the other first positioning post 131, and the third post 133 in sequence. The support base 20 is rotated toward the enclosure 10 to be received in the recessed portion 1022. In a closed position, the cable 40 is received in the recess space 23, and the support base 20 is coplanar with the raised portion 1021.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A display comprising:
an enclosure, the enclosure comprises a recessed portion and a first post located in the recessed portion;
a display body mounted in the enclosure;
a cable connected to the display body and received in the recess portion, the cable is wound around the first post; and
a support base pivotably mounted to the enclosure and received in the recess portion to enable the cable to be mounted between the support base and the enclosure.

2. The display of claim 1, wherein the display body comprises a connector; the recess portion comprises a bottom surface and a side surface connected to the bottom surface; the first post is placed on the bottom surface and the connector is mounted on the side surface; the cable comprises a cable body and a connecting head inserted in the connector; and the cable body is wound around the first post.

3. The display of claim 2, wherein the side surface is substantially perpendicular to the bottom surface.

4. The display of claim 2, wherein the enclosure further comprises a second post placed on the bottom surface; the cable body is wound around the first post and the second post.

5. The display of claim 2, wherein the display further comprises two pivot portions extending from the bottom surface; each of the two pivot portions defines a pivot hole;
and the support base comprises two pivot posts pivotably mounted in the two pivot holes.

6. The display of claim 5, wherein the support base defines two cutouts, and each of the two pivot post extends from the edge of each of the two cutouts.

7. The display of claim 1, wherein the enclosure defines first elongated through hole, and the support base defines a second elongated through hole aligned with the first elongated through hole.

8. A display comprising:
an enclosure, the enclosure comprises a first post and a second post;
a display body mounted in the enclosure;
a cable connected to the display body, the cable is wound around the first post and the second post; and
a support base pivotably mounted to the enclosure, the support base is capable of rotating toward the enclosure to enable the cable to be mounted between the support base and the enclosure.

9. The display of claim 8, wherein the enclosure comprises a recess portion; the first post and the second post are placed in the recess portion; the cable is received in the recess portion; and the support base is configured to rotates towards the enclosure to be received in the recess portion.

10. The display of claim 9, wherein the display body comprises a connector; the recess portion comprises a bottom surface and a side surface connected to the bottom surface; the first post is placed on the bottom surface and the connector is mounted on the side surface; the cable comprises a cable body and a connecting head inserted in the connector; and the cable body is wound around the first post.

11. The display of claim 10, wherein the side surface is substantially perpendicular to the bottom surface.

12. The display of claim 10, wherein the display further comprises two pivot portions extending from the bottom surface; each of the two pivot portions defines a pivot hole; the support base comprises two pivot posts pivotably mounted in the two pivot holes.

13. The display of claim 12, wherein the support base defines two cutouts, each of the two pivot post extends from the edge of each of the two cutouts.

14. The display of claim 8, wherein the enclosure defines first elongated through hole, and the support base defines a second elongated through hole aligned with the first elongated through hole.
